(19) United States
(12) Patent Application Publication
(10) Pub. No.: US 2006/0118039 A1
(43) Pub. Date: Jun. 8, 2006

(54) Spray device with touchless controls

(76) Inventor: Steven C. Cooper, Athens, GA (US)

Correspondence Address: Andre M. Szuwalski;JENKENS & GILCHRIST, A PROFESSIONAL CORPORATION, 1445 Ross Avenue, Suite 3700, Dallas, TX, 75202, US

(21) Appl. No.: 11/264,545

(22) Filed: Nov. 1, 2005

Related U.S. Application Data
(60) Provisional application No. 60/624,714, filed on Nov. 3, 2004.

(51) Int. Cl. B05C 11/00; C23C 14/00

(52) U.S. Cl. 118/696; 118/50

(57) ABSTRACT

A spray chamber control system includes at least one touch-free sensor connected to at least one input of a controller, and at least one control mechanism connected to at least one output of the controller. In accordance with an embodiment, the at least one touch-free sensor includes at least one door control sensor, and the control mechanism includes a door control mechanism adapted to control opening and closing of a spray chamber door. In accordance with another embodiment, the at least one touch-free sensor includes at least one spray control touch-free sensor, and the control mechanism includes a spray control mechanism adapted to control operation of at least one spray nozzle for dispensing a spray liquid.

### CROSS-REFERENCE TO RELATED APPLICATIONS

This application claims priority from and incorporates by reference the entire disclosure of U.S. Provisional Application No. 60/624,714 filed Nov. 3, 2004 and bearing Docket No. 32272-00151USPL.

### BACKGROUND OF THE INVENTION

1. Field of the Invention

The present invention relates to a system for uniformly delivering human body coating compositions. More particularly, the invention relates to methods and apparatus for operating the components of the spray device without touching control switches or other surfaces.

2. Background of the Invention

Automated systems for applying a spray mist to the entire body have recently been introduced and are primarily used for sunless tanning. There is also interest in automated spray systems for medicines and decontamination agents. (See, Law and Cooper, 2000 Institute of Physics, Edinburgh, Scotland UK). These systems, housed within cabinets or booths to permit enclosure of an adult, have the advantage of uniform self-application in a private setting without the need for an assistant. U.S. Pat. No. 5,922,333 to Laughlin, U.S. Pat. No. 6,387,081 to Cooper, U.S. Pat. No. 5,664,593 to McLain, and U.S. Pat. Nos. 6,302,122 & 6,443,164 to Parker describe automatic spray chambers for coating the human body. An early patent, U.S. Pat. No. 1,982,509 to Frank, discloses a vertically-traveling spray nozzle carriage system that is intended for applying sprays to the human body. Commercial versions of such spray systems use pushbutton switches pressed manually by the customers to activate the spray mechanisms. Several of these units have doors which are manually opened and closed by the customer.

Several companies now manufacture automated spray booths, to be used in tanning salons, for the purpose of more evenly applying sunless tanning compounds to the human skin. This new UV-free tanning method offers an alternative to salon customers who do not tan well in UV light or who do not wish to use conventional sun-lamp tanning beds. When used correctly, these sunless tanning systems are effective and consequently have been steadily increasing in popularity in tanning salons across, for example, the United States, Canada, Europe and Australia. The tanning solution most often used is water-based, containing up to 10% DHA, alcohol, aloe vera gel and coloring.

Most of these spray-tanning booths have many nozzles mounted on the walls of an enclosure. The many nozzles are positioned at various angles around the subject in an effort to apply an even coating. Typically, the customer is instructed to move through a variety of poses during the spray event which usually lasts less than 30 seconds. Other automated spray devices for sunless tanning use oscillating nozzle movement within the booth enclosure to further enhance spray coverage. Prior art automated booths for applications onto human subjects utilize manual switches activated by the customer to operate the spray session.

The interaction with these spray tanning systems by the customer is similar between the various types of spray booths commercially available. To prepare for the tanning session the customer applies a thick cream, often known as a barrier cream, to palms and nail areas of the hands to prevent unwanted tan stains on these areas. The cream needs to be placed carefully to prevent thinly applied or missed areas. The customer must be careful not to apply any cream onto skin areas where a tan is desired. After application of the barrier cream, the customer opens the door, if present on the booth, by hand and closes it behind him or her. This operation disturbs the coating of hand cream, removing some from the hand and leaving it on portions of the door. Furthermore, manual opening and closing of the door can cause the cream to be smeared onto unwanted areas of the hand. After moving to the inside of the chamber, the customer depresses a switch to activate the tanning session. This further disturbs the hand cream and leaves cream on switch surfaces. During the tanning session a spray mist is applied to the body parts. Mist overspray coats interior portions of the spray booth enclosure, including the manual switches and the door handles which is undesirably transferred to the customer's skin surface upon contact, causing dark spots on unwanted areas. After the tanning session the customer pushes open the door, again leaving barrier cream on door surfaces and transferring tanning compound from the booth to portions of the hand where a tan is not desired. After the customer completes the session and leaves, the salon attendant must clean the thick cream from all of the areas of the booth touched by the customer. In addition, cream and tanning compound, when mixed, can create stains on the booth surfaces which are very difficult to remove. In addition, the cream and tanning compound penetrates into switch mechanisms, shortening the life of the switches.

A door on the spray tanning booth is useful for containing any mist present during the tanning session and lingering afterward. The customer does not wish to touch a manually operated door so it is often left open by the customer after the session, causing lingering mist to escape and settle onto areas outside of the spray booth. Spring door closers have been used to eliminate this problem. However they increase the force necessary to open the door. In addition, they must be somewhat sophisticated in design to keep the door from closing too rapidly and allowing the door to be held open during times when the booth is being serviced or aired out.

### BRIEF SUMMARY OF THE INVENTION

The preceding discussion illustrates the need for the spray device for human subjects according to embodiments of the present invention in which operation of spray system functions is by touch-free means. Embodiments of the described invention prevent disruption of the intended coating on the human as well as prevent transfer of sprayed material or pre-spray preparations between the human subject and the components of the spray device.

Embodiments of the present invention further provide for improved operation of spray devices intended for applications onto human subjects by incorporating touch-free sensors to control the main functions of the spray device. These functions may include opening and closing of enclosure doors when present, and activating the spray process. In at least one embodiment of the present invention, the preferred type of sensor is an infrared reflective switch, although proper operation may be achieved with other types of known sensors, including those activated by light, voice, motion, inductive means or capacitive means. In at least one embodiment of the present invention it is desirable that the activation distance be limited to less than 10 inches in order to avoid misactivation. In embodiments of the present invention it is desirable that the touch-free sensors be used with logic circuitry or computer controllers for improved performance features such as: delayed timing before start of spray, blocked sensor detection, malfunctioned sensor detection, prohibiting automatic door opening during a spray session, allowing for door opening by manual means at any time, or holding the door open during servicing. Other touch-free sensors may be used to detect the physical size of the human subject undergoing a spray session and adjust the spray device accordingly.

In a spray chamber control system in accordance with an embodiment of the present invention includes a controller having at least one input and at least one output; at least one touch free sensor connected to the at least one input of the controller; and at least one control mechanism connected to the at least one output of the controller. In accordance with another embodiment the at least one touch free sensor can comprise at least one door control sensor and the control mechanism comprises a door control mechanism adapted to control opening and closing of a spray chamber door. In accordance with still another embodiment, the at least one touch free sensor can comprise at least one spray control touch free sensor and the control mechanism comprises a spray control mechanism adapted to control operation of at least one spray nozzle for dispensing a spray liquid.

### BRIEF DESCRIPTION OF THE DRAWINGS

FIG. 1 illustrates a spray chamber containing an embodiment of a touch-free spray device according to the present invention; and

FIG. 2 illustrates a spray chamber control system in accordance with an embodiment of the present invention.

### DETAILED DESCRIPTION OF THE DRAWINGS

Embodiments of the present invention provide for a spray device for human subjects in which at least one component is controlled by at least one touch-free sensor. Touch-free sensor types may include optical, voice, motion, inductive, capacitive sensors and other known sensor types.

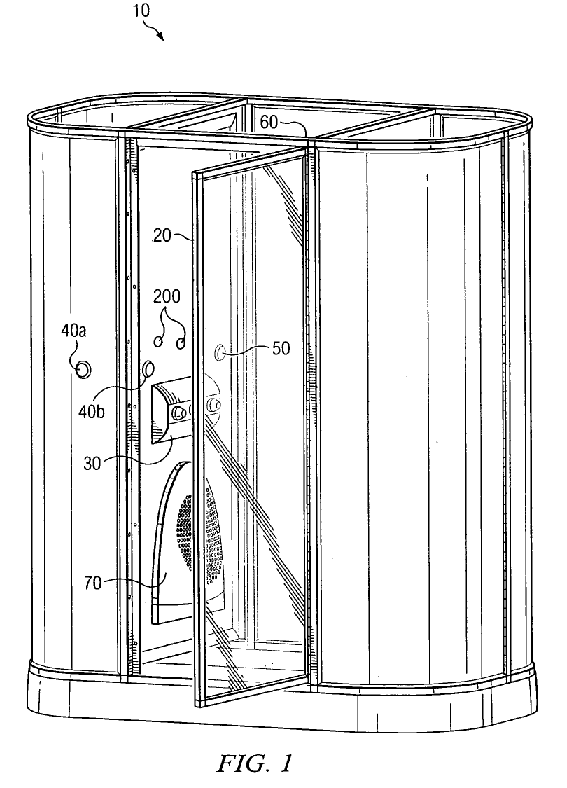

Referring now to FIG. 1, a spray chamber including one embodiment of a touch-free spray device according to the present invention is illustrated. FIG. 1 illustrates a spray chamber 10 with a door 20 surrounding a spray device for coating human subjects. The spray system further includes one or more spray nozzles 30 used to apply a spray treatment to human skin. The spray treatments may be, for example, for applications of cosmetic ingredients, such as sunless tanning. Other uses include applications of medicines, sunscreen, skin moisturizers, vitamins or decontamination agents. The spray system further includes one or more touch free sensors, which may include, for example, door control touchless sensors 40a, 40b and at least one spray control touchless sensor 50. The functions under control by the touch free sensors may include at least one of the following: spray nozzle operation, door opening, door closing, session type selection, or spray settings depending on sensing human body size. Touch free sensors located in proximity to the spray device are activated by the operator without contacting any part of the spray system. Touch free operation according to embodiments of the present invention prevents unwanted transfer of sprayed material to the operator or unwanted transfer of lotions or spray material to spray system components before and after the spraying operation.

According to the embodiment shown in FIG. 1, a customer or other spray subject, holds a hand in front of the touch-free (or touchless) sensor 40a on the outside of the spray chamber 10, which in turn signals a controller to activate a door opening/closing mechanism. This door opening/closing mechanism may include an electric motor drive or preferably a pneumatic cylinder which moves a door pivot lever 60 to open or close the door 20. The door opening mechanism may further include a relief so that the door 20 may be manually opened at any time. Once the customer is inside the spray chamber 10, the door 20 may close automatically after a set time, or preferably the door is closed by the customer by activating a touch-free (touchless) sensor 40b located inside of the spray chamber 10. After the door 20 closes, the customer can activate the spray session sequence with the same inside touch-free sensor 40b or optionally an additional touch-free (touchless) sensor, such as the spray control touchless sensor 50. In still another embodiment, a controller may be used to control the closing of the door 20 after a predetermined period of time has elapsed.

The spray system may further include a controller, such as computer logic control, that may be used, for instance, to not allow the spray session to begin if the door has not been closed. The spray nozzles 30 may be mounted to a stand or to the walls of a chamber. In still other embodiments, the spray nozzles 30 may be mounted to an oscillating sprayer drum within the spray chamber 10 as shown in FIG. 1. The spray nozzles 30 spray for a predetermined period of time so as to coat at least a portion of the human subject with adequate spray. This time may be selectable by activating a touch-free sensor, such as spray control touchless sensor 50, or set by a computer controller. After the spray session, the door mechanism may open the door 20 automatically or the door mechanism may be activated by holding a hand in front of the door control touchless sensor 40b on the inside of the booth. During the spray session it is preferred that the door 20 is held closed by the door mechanism. However, for safety, embodiments of the present invention may include a door opening mechanism attached to the door pivot lever 60 that includes a relief mechanism to enable the door 20 to be opened manually at any time from the inside or the outside of the spray chamber 10.

Still referring to FIG. 1, the spray chamber 10 may be provided with spray mist exhaust fan 70 which may be used to exhaust residual mist present in the spray chamber 10 after or during a spraying operation, preferably before the door 20 is opened. The controller may further be adapted to perform a variety of functions such as delay timing before start of spray, detect a blocked sensor, detect a malfunctioned sensor, prohibit automatic door opening during a spray session, allow for door opening by manual means at any time, or hold the door open during servicing.

Although the spray chamber 10 of FIG. 1 is illustrated as being of a size to accommodate an entire body of a human subject, it should be understood that in various other embodiments, the spray chamber may be sized to accommodate only a portion or a part of the body of a human subject so as only to coat that desired portion, for example, an arm, a leg, a head, a torso, etc. In various other embodiments, the spray chamber may be sized to accept one or more portions of a human body for coating.

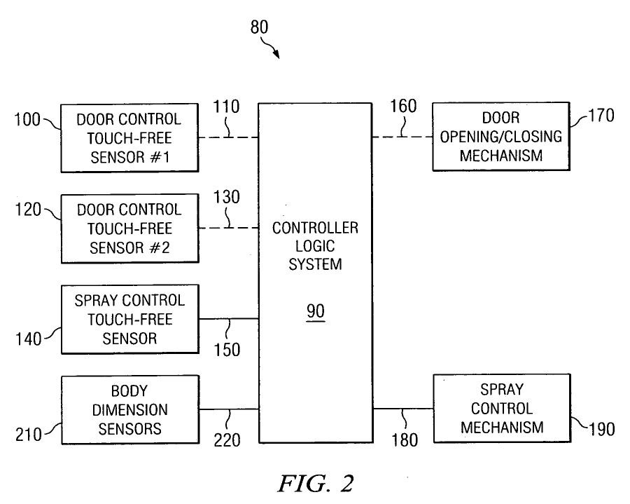

Referring now to FIG. 2, a spray chamber control system in accordance with an embodiment of the present invention is illustrated. The spray chamber control system 80 includes a controller logic system 90 that functions to control various operations of the spray chamber 10. The controller logic system 90 may be comprised of, for example, a processor, a programmable logic controller or a computer. A door control touch-free sensor #1 (100) located on an exterior portion of the spray chamber, or alternately another location on the outside of the spray chamber, is connected to a first input 110 of the controller logic system 90. A door control touch-free sensor #2 (120) placed at a location in the interior of the spray chamber, is connected to a second input 130 of the controller logic system 90. At least one spray control touch-free sensor 140 located within the spray chamber is connected to a third input 150 of the controller logic system 90.

Still referring to FIG. 2, a first output 160 of the controller logic system 90 is connected to a door opening/closing mechanism 170 which functions to open and close the door of the spray chamber. The door opening/closing mechanism 170 may comprise, for example, an electric motor drive or a pneumatic cylinder which moves a door pivot lever to open and close the door. A second output 180 of the controller logic system 90 is connected to a spray control mechanism 190 that functions to control the operation of one or more spray nozzles (such as spray nozzles 30 illustrated in FIG. 1) for applying a spray liquid to a subject within a spray chamber.

During an example operation of the spray chamber control system of FIG. 2, a customer holds a hand in front of door control touch-free sensor #1 (100), which then sends a signal to the controller logic system 90. In response to the signal from door control touch-free sensor #1 (100), the controller logic system 90 outputs a signal to the door opening/closing mechanism 170 which indicates to the door opening/closing mechanism 170 to open the door of the spray chamber. Once the customer enters the spray chamber through the door, the customer holds a hand in front of the door control touch-free sensor #2 (120), which then sends a signal to the controller logic system 90.

In response to the signal from the door control touch-free sensor #2 (120), the controller logic system 90 outputs a signal to the door opening/closing mechanism 170 which indicates to the door opening/closing mechanism 120 to close the door of the spray chamber. Alternately, the controller logic system 90 may automatically output a signal to the door opening/closing mechanism 170 indicating to the door opening/closing mechanism 170 to close the door after a predetermined period of time. After the door is closed, the customer can activate the spray session sequence by holding a hand in front of the spray control touch-free sensor 140. In response, the spray control touch-free sensor 140 sends a signal to controller logic system 90 which then sends control signals to the spray control mechanism 190 to control the operation of the spray control mechanism 190 in accordance with the spray session sequence. The spray control mechanism controls the operation of one or more spray nozzles which function to dispense a spray liquid to at least a portion of a subject within the spray chamber. In various embodiment the one or more spray nozzles may be controlled to dispense a spray liquid to coat the surface of one or more portions, or the entire surface, of a human subject.

In accordance with one embodiment of the invention, during the spray session sequence the spray control mechanism may pause the spraying operation one or more times, and the subject may be prompted, for example by a visual or audio prompt, to reorient themselves within the spray chamber. For example, the subject may be prompted to turn 180 degrees within the spray chamber so that an opposite side may be sprayed. After a predetermined period of time or in response to activation of the spray control touch-free sensor 140 by the subject, the spraying operation may resume. In an alternate embodiment, the spray chamber may be provided with spray nozzles oriented in a variety of directions such that the entire body of the subject may be sprayed without requiring reorientation of the subject.

The spray chamber may further be provided with additional touch-free sensors connected to further inputs of the controller logic system 90 which may provide control over a variety of spray control operations such as selection of a desired spray solution, control of a spraying time, etc.

In accordance with another embodiment of the present invention, the spray chamber may be provided with one or more touch free sensors 200 as illustrated in FIG. 1 to sense the size or one or more other dimensions of a body within the spray chamber. For example, the spray chamber may be provided with one or more touch free sensors 200 to determine the height and/or width of a body within the chamber. This body height and width information can then be provided to a processor or controller which uses this dimensional information to determine a size type of the body, and control the spray settings of the nozzles accordingly. For example, if the body type is determined to be of a large size, the processor or controller can control the nozzles to dispense a comparatively larger volume of spray liquid than that dispensed to a medium or small body size. This provides the benefit of allowing the proper amount of spray liquid to be dispensed to a particular body type while avoiding undesirable overspray or underspray. A spray control system in accordance with this embodiment is illustrated in FIG. 2 in which body dimension sensors 210 are connected to one or more inputs 220 of the controller logic system 90 to provide body dimension information to the controller logic system 90. The controller logic system 90 may further use this body dimension information to control the spray control mechanism 190.

In accordance with another embodiment of the present invention, the processor or controller can use the height and/or width information to control a sweeping range of the nozzles so that the sweeping range is confined within the dimensions of the body. This provides the benefit of conserving the liquid spray and reducing the amount of spray deposited on the walls of the spray chamber. Other spray operations that may also be controlled in response to the determination of body size by the touch free sensors include activation of the spray nozzles, controlling the spray of particular nozzles, and controlling the spray time of the nozzles.

A variety of types of touchless/touch-free sensors may used in accordance with embodiments of the present invention. For example, touchless sensors using passive infrared detection, active infrared detection, induction triggers, voice activation, radar and other reflected RF energy detection, visible light detection, etc. Examples of touchless/touch-free sensors that may be used in accordance with embodiments of the present invention are described in U.S. Pat. Nos. 5,577,660; 5,603,127; 5,868,311; 6,067,673; 6,206,340; 6,250,601; 6,388,609; 6,390,329; 6,481,634; 6,513,787; 6,568,655; 6,596,983; and RE 037,888, all incorporated herein by reference.

Some of the advantages provided by embodiments of the described invention include prevention of disruption of the intended coating on the human, as well as prevention of transfer of sprayed material or pre-spray preparations between the human subject and the components of the spray device.

Although the various embodiments of the present invention have been described for use in the application of tanning solutions to a human subject, it should be understood that the present invention can also be applied to other cosmetic spray applications, as well as for the application of medicinal and decontaminant sprays, for example, antibiotics, antitoxins, disinfectants, sanitizers, etc. Further, although a preferred embodiment of the method and apparatus of the present invention has been illustrated in the accompanying Drawings and described in the foregoing Detailed Description, it is understood that the invention is not limited to the embodiment disclosed, but is capable of numerous rearrangements, modifications, and substitutions without departing from the spirit of the invention as set forth and defined by the claims.

What is claimed:

1. A spray chamber control system comprising:
a controller having at least one input and at least one output;
at least one touch free sensor connected to the at least one input of the controller; and
at least one control mechanism connected to the at least one output of the controller; and
wherein the at least one controller is adapted to receive a first signal from the at least one touch free sensor and send at least one control signal to the control mechanism.

2. The spray chamber control system of claim 1, wherein the at least one touch free sensor comprises at least one door control sensor and the control mechanism comprises a door control mechanism adapted to control opening and closing of a spray chamber door.

3. The spray chamber control system of claim 2 wherein the door control mechanism comprises at least one of an electric motor drive, and a pneumatic cylinder connected to a door.

4. The spray chamber control system of claim 2, wherein the controller is further adapted to control operation of the door after a predetermined period of time has elapsed.

5. The spray chamber control system of claim 2, wherein the at least one door control sensor comprises a first door control sensor located on an outside surface of a spray chamber.

6. The spray chamber control system of claim 2, wherein the at least one door control sensor comprises a second door control located on an inside surface of a spray chamber.

7. The spray chamber control system of claim 1, wherein the at least one touch free sensor comprises at least one spray control touch free sensor and the control mechanism comprises a spray control mechanism adapted to control operation of at least one spray nozzle for dispensing a spray liquid.

8. The spray chamber control system of claim 7, wherein the at least one spray control touch free sensor is located on an inside surface of a spray chamber.

9. The spray chamber control system of claim 1, wherein the controller comprises at least one of a processor, a controller logic system, a programmable logic controller, or a computer.

10. The spray chamber control system of claim 1, wherein the at least one touch free sensor is adapted to detect at least a portion of a human subject.

11. A spray chamber comprising:
a controller having at least a first input and at least one output;
at least one spray control touch free sensor connected to the at least a first input of the controller; and
at least one spray control mechanism connected to the at least one output of the controller; and
at least one spray nozzle adapted to dispense a spray liquid to coat the surface of a subject; and
wherein the controller is adapted to receive a first signal from the at least one spray control touch free sensor and send at least a first control signal to the spray control mechanism to control dispensing of a spray liquid from the at least one nozzle.

12. The spray chamber of claim 11, wherein the at least one controller comprises at least one of a processor, a controller logic system, a programmable logic controller, or a computer.

13. The spray chamber of claim 11, wherein the at least one spray control touch free sensor is located on an inside surface of the spray chamber.

14. The spray chamber of claim 11, wherein the spray chamber further comprises:
an exhaust fan adapted to exhaust spray liquid mist from the spray chamber.

15. The spray chamber of claim 11, further comprising:
at least one body dimension sensor connected to at least a second input of the controller, wherein the controller is further adapted to receive a second signal from the at least one body dimension sensor and send at least a second control signal to the spray control mechanism to control dispensing of a spray liquid from the at least one nozzle in accordance with the second signal.

16. The spray chamber of claim 15, wherein the second signal from the at least one body dimension sensor comprises at least one of a height of a spray subject and a width of the subject.

17. The spray chamber of claim 15 further comprising:
an oscillating sprayer drum adapted for mounting of the at least one nozzle thereto, wherein the controller is further adapted to control a sweeping range of the oscillating spray drum in response to the at least a second control signal.

18. The spray chamber of claim 11, wherein the controller is further adapted to control at least one of a selection of a spray solution and a spraying time in response to the at least a first control signal.

19. The spray chamber of claim 11, wherein the at least one spray control touch free sensor is adapted to detect at least a portion of a human subject.

20. The spray chamber of claim 11, wherein the spray chamber is of a size to accommodate an entire body of a human subject.

21. The spray chamber of claim 11, wherein the spray chamber is of a size to accommodate at least one portion of a body of a human subject.

22. A spray chamber comprising:
a spray chamber door;
a controller having at least a first input and at least one output;
at least one door control touch free sensor connected to the at least one first input of the controller; and
at least one door control mechanism connected to the at least one output of the controller; and
wherein the controller is adapted to receive a first signal from the at least one door control touch free sensor and send at least a first control signal to the at least one door control mechanism to control operation of the spray chamber door.

23. The spray chamber of claim 22, wherein the control operation comprises at least one of an opening and closing of the spray chamber door.

24. The spray chamber of claim 22 wherein the door control mechanism comprises at least one of an electric motor drive, and a pneumatic cylinder connected to a door.

25. The spray chamber of claim 22, wherein the at least one door control touch free sensor comprises a first door control touch free sensor located on an outside surface of the spray chamber.

26. The spray chamber of claim 22, wherein the at least one door control touch free sensor comprises a second door control touch free sensor located on an inside surface of the spray chamber.

27. The spray chamber of claim 22, wherein the controller is further adapted to control operation of the door after a predetermined period of time has elapsed.

28. The spray chamber of claim 22, further comprising:
at least one spray nozzle adapted to dispense a spray liquid to coat the surface of a subject.

29. The spray chamber of claim 28, further comprising:
at least one spray control touch free sensor connected to at least a second input of the controller;
wherein the controller is further adapted to receive a second signal from the at least one spray control touch free sensor and send at least a second control signal to the spray control mechanism to control dispensing of the spray liquid from the at least one nozzle.

30. The spray chamber of claim 22, wherein the spray chamber further comprises:
an exhaust fan adapted to exhaust spray liquid mist from the spray chamber.

31. The spray chamber of claim 22, wherein the at least one door control touch free sensor is adapted to detect at least a portion of a human subject.

32. The spray chamber of claim 22. wherein the spray chamber is of a size to accommodate an entire body of a human subject.

33. The spray chamber of claim 22, wherein the spray chamber is of a size to accommodate at least one portion of a body of a human subject.
